(19) United States
(12) Patent Application Publication
(10) Pub. No.: US 2024/0290726 A1
(43) Pub. Date: Aug. 29, 2024

(54) METHOD FOR MANUFACTURING A SMARTCARD MODULE AND SMARTCARD MODULE OBTAINED USING THIS METHOD

(71) Applicant: EYCO, Trets (FR)

(72) Inventor: Éric EYMARD, Mougins (FR)

(73) Assignee: EYCO, Trets (FR)

(21) Appl. No.: 18/567,467

(22) PCT Filed: May 30, 2022
(86) PCT No.: PCT/EP2022/064651

§ 371 Date: Dec. 6, 2023

(30) Foreign Application Priority Data
Jun. 7, 2021 (FR) FR2105980

(51) Int. Cl. H01L 23/538; G06K 19/077; H01L 21/48; H01L 23/00; H01L 23/66

(52) U.S. Cl. CPC H01L 23/5388; G06K 19/07722; H01L 21/4853; H01L 21/4857; H01L 23/5383; H01L 23/5386; H01L 23/5389; H01L 23/66; H01L 24/19; H01L 24/20; H01L 2223/6677; H01L 2224/214

(57) ABSTRACT

The invention relates to a method for manufacturing a smartcard module wherein an electronic component is mounted on an upper face of a metal foil and then covered with a first layer of dielectric material. Openings are made in the first layer of hardened dielectric material and then everything is covered with a conducting layer that fills the openings. The metal foil and the conducting layer are etched so as to create patterns of conductors. The invention also relates to a smartcard module wherein an integrated circuit is placed between a first and a second metallic layer inside a layer of dielectric material. The invention also relates to the smartcard module thus obtained.

### TECHNICAL FIELD

The present invention relates to a method for manufacturing a smartcard module, as well as a smartcard module obtained by said method. More generally, the invention relates to the manufacture of a smartcard module integrating at least one component into the thickness of the printed circuit of said module.

### TECHNOLOGICAL BACKGROUND

In the field of smartcards, the module of a card consists of a grid of contacts on which an integrated circuit (also called a “chip”) is connected, said module being inserted into the card so that the integrated circuit is inside said card with the contacts flush with the surface of the card. The contact grid is made according to a single—or double—sided flexible printed circuit board manufacturing technique, an etched face of which corresponds to the contact grid and the other face is used to receive and connect the chip to the contact grid. The chip is connected to the printed circuit, according to a technique using gold wire-bonding, or according to a technique of directly welding the overturned chip to the printed circuit (better known as the “flip-chip” technique). Once the chip is connected, it is covered with a resin in order to protect it, according to a technique making it possible to control the thickness of resin. The module thus produced corresponds to a rectangular disc of printed circuit board having a thickness of between 150 and 200 microns with a protuberance on the order of 300 to 400 microns at the center of the face opposite the contact grid.

As an example, application US 2004/256150 illustrates the production of a printed circuit for a chip card module intended to receive a chip according to the so-called flip-chip technique. U.S. Pat. No. 6,319,827 discloses an NFC antenna placement technique on a chip intended to be placed in a smartcard module according to the so-called wire-bonding technique.

In order to place the module in a smartcard, the latter must comprise a first cavity having the shape of the rectangular disc and the thickness of the printed circuit, and a second cavity placed in the center of the first cavity to receive the protuberance of the module so that the grid of contacts is flush with the surface of the card. Such first and second cavities may be made by machining or by molding. Since the thickness of a smartcard is 800 micrometers, this creates a brittle zone at the module, which may also have a perceptible deformation after assembly. Furthermore, the creation of the double cavity has a non-negligible cost.

Furthermore, the thickness of the smartcard requires a printed circuit having a thickness of less than 200 micrometers in order to allow the integrated circuit and its protective layer to be received over a thickness of less than 400 micrometers. The production of this thin a printed circuit requires reducing all the thicknesses of the layers constituting the printed circuit, which makes it very flexible and limits the size of the chip to prevent it from breaking due to a degree of bending not tolerated by the silicon constituting the integrated circuit.

### SUMMARY OF THE INVENTION

The invention proposes a method for manufacturing a smartcard module that incorporates a component, such as for example a silicon chip, in the thickness of its printed circuit. By virtue of such a method, it becomes possible to produce a smartcard module of homogeneous thickness, without a protrusion, the thickness of which is less than the thickness of a module of the prior art. As the printed circuit is thicker than the printed circuits of the prior art, it can be less flexible and allow the use of a chip of larger surface area. Furthermore, since the chip is placed and connected during the manufacturing of the printed circuit, the manufacturing costs of the module are reduced.

More particularly, the invention proposes a method for manufacturing a smartcard module that comprises the steps of:
providing a first metal foil comprising at least one marker,
depositing and bonding at least one electronic component on an upper face of said metal foil at a location positioned relative to the at least one marker,
depositing a first layer of dielectric material on the upper face of the metal foil and on the electronic component,
making openings in the first layer of hardened dielectric material,
depositing a first conducting layer covering the entire surface of the first layer of dielectric material,
depositing a second conducting layer filling the openings,
etching the first metal foil and the first conducting layer in order to create patterns of conductors, the etching of the first metal foil forming a smartcard contact grid.

According to a first embodiment, the steps of depositing the first and second conducting layers can be carried out simultaneously and comprise a step of depositing a conductive priming material on the first layer of dielectric material and in the openings, followed by a step of electrodeposition of copper.

According to a second embodiment, the step of depositing the first conducting layer can be done by depositing a second metal foil prior to the hot rolling step, and the step of producing openings simultaneously produces openings in the first layer of dielectric material and in the second metal foil.

Preferably, the step of producing openings can be done by laser.

Depending on the choice of the person skilled in the art, the dielectric material may be chosen from one of the following materials: polyester, epoxy resin, polyimide.

In a preferred embodiment, the first layer of dielectric material may be a thermosetting material deposited in the liquid or pasty phase and wherein the method comprises a step of hot rolling in order to flatten and harden the first layer of dielectric material.

In order to best control the thickness of the printed circuit, the hot rolling step can be carried out using a press that can control the pressing height.

In order to etch the printed circuit by photolithography, the step of etching the first metal foil and the first conducting layer may comprise the steps of:
depositing photosensitive layers on the first conducting layer and on the bottom surface of the first metal foil,
exposing the photosensitive layers with a negative mask of the patterns defining the parts to be insulated,
removing the insulated part of the photosensitive layers,
acid-etching the first conducting layer and the bottom surface of the first metal foil on the areas where the insulated photosensitive layers have been removed.

To produce one or more other metallization levels at the end of the step of etching the first conducting layer, said method may comprise the following steps:
depositing a second layer of dielectric material on the first etched conducting layer,
hot-rolling in order to flatten and harden the second layer of dielectric material,
making openings in the second layer of hardened dielectric material,
depositing a third conducting layer covering the entire surface of the second layer of dielectric material,
depositing a fourth conducting layer filling the openings,
etching the third conducting layer in order to produce patterns of conductors.

Similar to the etching of the other conducting layers, the step of etching the third conducting layer may comprise the steps of:
depositing a photosensitive layer on the third conducting layer,
insulating the photosensitive layer with a mask defining the parts to be insulated,
removing the insulated part of the photosensitive layer,
acid-etching the third conducting layer on the areas where the insulated photosensitive layer has been removed.

According to another aspect, the invention proposes a smartcard module comprising a first metallic layer and a second metallic layer enclosing a layer of dielectric material, the first metallic layer defining a grid of contacts intended to be flush with the surface of a smartcard, the second metallic layer being etched with patterns defining metal conductors to connect contact pads of a circuit integrated into the grid of contacts through openings made in the layer of dielectric material, characterized in that the integrated circuit is placed between the first and second metallic layers inside the layer of dielectric material.

According to a particular embodiment, the module may comprise a third metallic layer separated from the second metallic layer by a second dielectric layer, the second metallic layer being between the first and third metallic layers.

### BRIEF DESCRIPTION OF THE FIGURES

The invention will be better understood, and other features and advantages thereof will become apparent on reading the following description of particular embodiments of the invention, given by way of illustrative and non-limiting examples, and referring to the appended drawings, among which:

FIG. 1 shows a copper strip serving as a basis for the production of a smartcard module strip according to the method of the invention,

FIG. 2a, FIG. 2b, FIG. 2c, FIG. 2d, FIG. 2e, FIG. 2f, FIG. 2g and

FIG. 2h illustrate the steps of a first embodiment of the method according to the invention,

FIG. 3a and FIG. 3b show a strip of smartcard modules produced by the method according to the invention,

FIG. 4a, FIG. 4b, FIG. 4c, FIG. 4d and FIG. 4e illustrate the steps of a second embodiment of the method according to the invention,

FIG. 5a, FIG. 5b, FIG. 5c, FIG. 5d and FIG. 5e illustrate the steps of an alternative embodiment of the method according to the invention,

### DETAILED DESCRIPTION

In the following description, several alternative embodiments will be described. In order to simplify the description, the elements located in multiple figures will use the same references and will be described only once. In the various alternative embodiments, only the modified elements will be explained in relation to an example described above.

For the sake of explanation, the drawings are not to scale, in order to be able to depict details in the same figure that could not be visible if the scale was respected. To this end, reference should be made to the description to have a more precise idea of the quantities shown.

In order to remove any doubt of interpretation, the term “smartcard module” in the present document refers to a module intended to be inserted into a cavity of a smartcard body and which comprises at least one chip connected a contact grid intended to be flush with the surface of said smartcard.

The manufacturing method of the invention is particularly attractive for the production of continuous smartcard modules over strips of several meters, or even several tens of meters, the width of which is generally from 35 to 150 millimeters. Thus, the description principally refers to the manufacture of a smartcard module on 35-millimeter strips but can be implemented on wider strips.

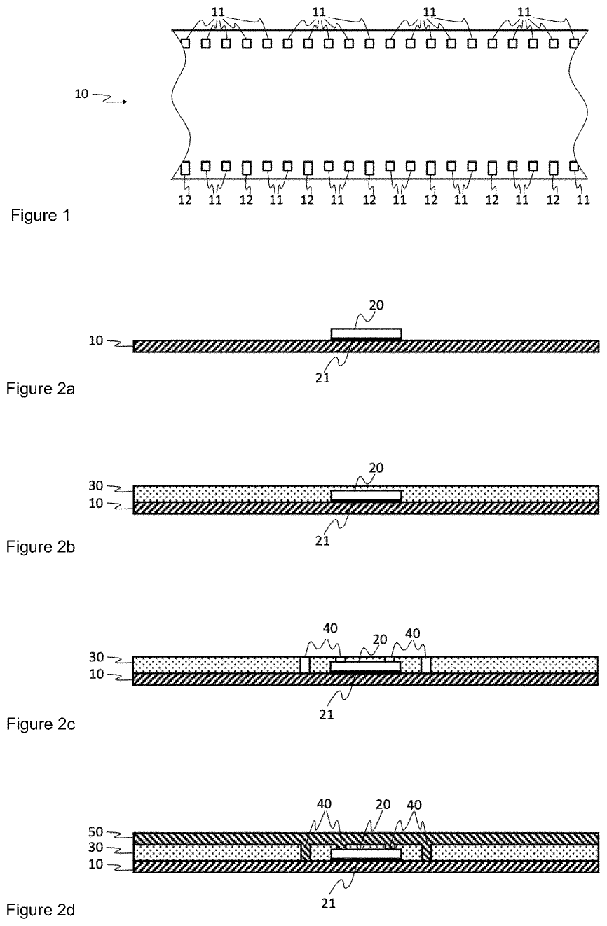

The method according to the invention begins by providing a metal foil. In order to be able to produce a strip of modules, the metal foil is for example a strip of copper 10 of 35 millimeters wide, shown in FIG. 1. The copper strip 10 comprises perforations 11 and 12 on the edges which are intended to allow controlled advance on a manufacturing chain. Some perforations 12 are wider in order to serve as markers making it possible to define the positions of the modules on the metal strip. The markers 12 are in particular used in the method according to the invention to precisely define placement or machining positions.

In one variant, it is possible for all the perforations to be markers. This is the case in particular if the perforations are spaced apart by a distance corresponding to the gap between two modules. In contrast, the markers can also be distinct from the perforations used for to move the strip forward. According to the invention, it is important to have at least one marker on the metal strip on which the manufacturing method is implemented.

The metal strip 10 is for example a strip of copper, the thickness of which is for example 35 μm to produce a smartcard module. A person skilled in the art can use a different material than copper, such as steel or aluminum, for example, and the thickness of the metal strip 10 may vary depending on the applications for which the module is intended.

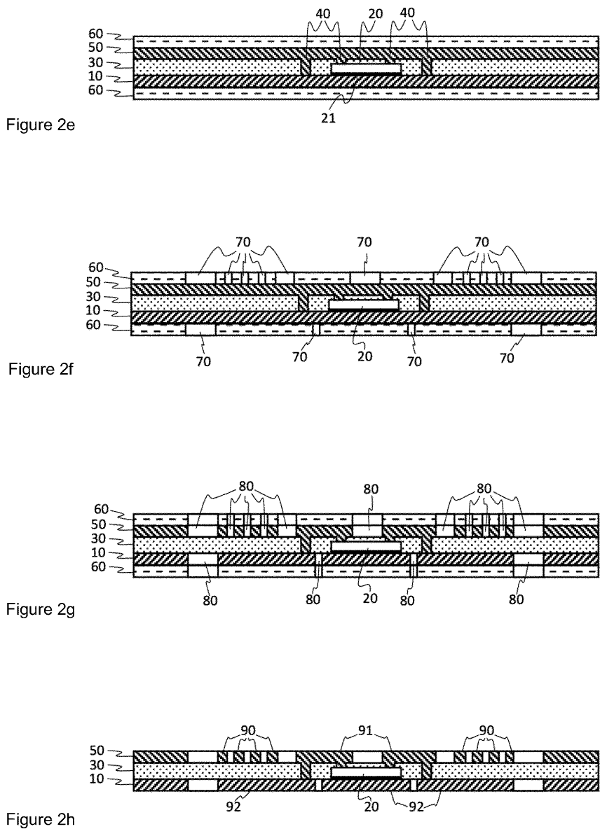

FIGS. 2a to 2h illustrate the various steps implemented according to a first embodiment of the method. In FIG. 2a, the metal strip 10 is positioned under a component placement tool. Since the position of the strip is identified by the placement tool using the marker 12, the tool performs a step of depositing and bonding an electronic component 20 to a location positioned relative to the marker. In the case of a smartcard module, the electronic component 20 is an integrated circuit of the thin silicon chip type directly cut from a wafer having a thickness for example of the order of 150 μm. The adhesive component 20 is bonded by a known technique using a thin layer adhesive 21 commonly used for manufacturing a smartcard module. The adhesive 21, for example a drop of epoxy glue, is placed on the component 20 or on the strip 10, then the component 20 is placed on the strip 10 and a pressure is applied to the component reducing the drop of glue to a thin layer of a thickness of the order of 10 μm to 20 μm and ensuring bonding on the strip. Other bonding techniques can be used, provided that the thickness of the layer of glue is of the same order of magnitude.

FIG. 2b shows a following step of depositing a layer of a dielectric material 30. The dielectric material 30 may be epoxy resin, polyimide, polyester, or any other material commonly used as dielectric material. According to a preferred embodiment, the dielectric material 30 is deposited in liquid or pasty phase, that is to say that the liquid phase has a viscosity sufficient to not creep without stress, the viscosity depending on the thickness of the dielectric material deposited. The deposition of the dielectric material is carried out as the strip 10 moves forward, with a flow rate of liquid material calculated to obtain a desired thickness. For a smartcard module, the flow rate is controlled to obtain a thickness on the order of 200 μm on the part of the strip that does not comprise the chip and on the order of 35 μm on the electronic component. The dielectric layer can then be UV-crosslinked or thermoset.

In order to obtain better control of the thickness of the dielectric layer 30, it is preferred to use a dielectric material of the thermosetting type and to carry out hot rolling by controlling the pressing height in order to flatten and harden said dielectric layer 30. In this respect, it is possible to deposit a release film on the dielectric layer in the pasty phase and then to hot-roll the whole assembly. The release film is removed after hot-rolling.

Hot-rolling can be done by moving the strip 10 covered with the dielectric layer 30 and the release film between cylinders separated by a predetermined distance corresponding to the desired distance for the dielectric layer 30, However, the use of cylinders can create stress on a silicon chip which risks damaging it if the thickness of dielectric material is small.

In the case of a smartcard module, it is desired to have the smallest possible thickness. Also, it is preferred to use a hot-rolling technique using a press at a controlled height such as for example described in the French patent application filed on Mar. 29, 2021 under number 2103188. Such a technique consists of stopping the movement of the strip 10 under a press that descends vertically to a predetermined height in order to apply pressure and heat to harden the dielectric material. The press is then opened and the strip 10 advances far enough to change the pressing zone. Thus, it is possible to obtain a dielectric layer 30 of a controlled thickness which is relatively planar.

The dielectric layer 30 having been hardened, a step of producing openings 40 is then carried out, as shown in FIG. 2c. The creation of the openings 40 is carried out for example using a YAG laser which will vaporize the dielectric material at locations corresponding to contact locations. The contact locations are positioned relative to the marker so that the openings correspond to contact pads of the integrated circuit 20 and to locations where it is desired to make contact with the metal strip 10. For more accuracy or alternatively, the positioning of the locations of the contact terminals of the integrated circuit 20 can also be done by X-ray position reading.

Then, a conducting layer 50 is deposited as shown in FIG. 2d. The conducting layer 50 is deposited to cover the entire dielectric layer 30 and to fill the openings 40. As an example, the conducting layer 50 is deposited in two stages. Firstly, a deposition of conductive priming material is deposited over the entire surface and then an electro-deposition of a more conductive metal, for example copper, is then carried out on the layer of conductive priming material to improve the conductivity of the conducting layer 50. The conductive priming material may be of different natures and the deposition method can vary as a function of the material. According to a preferred embodiment, the conductive priming material is for example carbon, graphite or palladium and the deposition is carried out by immersing the strip in a bath containing the conductive priming material so that the latter is deposited on the dielectric layer 30. Once the dielectric layer 30 is covered with a thin layer of conductive material, the strip is taken into a second bath to carry out the electrodeposition until a copper layer about 35 μm thick is obtained. The conducting layer 50 thus produced is connected to the metal strip 10 and to the contact areas of the chip.

Alternatively, the conducting layer 50 can be produced by vacuum sputtering of a metal. The sputtering may be used for the deposition of a conductive priming layer or to deposit the conducting layer 50 in full. However, the implementation of deposition by sputtering is more expensive, in particular if the amount of metal to be deposited is significant.

To obtain the module, a step of etching the conducting layer 50 and the metal strip 10 is then carried out according to a known technique. As a preferred example, the etching step is carried out by photolithography and acid attack. However, other etching methods could be used. In the preferred example, as shown in FIG. 2e, layers 60 of photosensitive material are deposited on the metallic layer 50 and on the lower surface of the metal strip 10. The parts 70 to be removed from the photosensitive layers 60 are then exposed to UV using a mask, not shown, and then these parts 70 are removed, as shown in FIG. 2f. The strip is then passed into an acid bath in order to make openings 80 in the metal strip 10 and in the conducting layer 50.

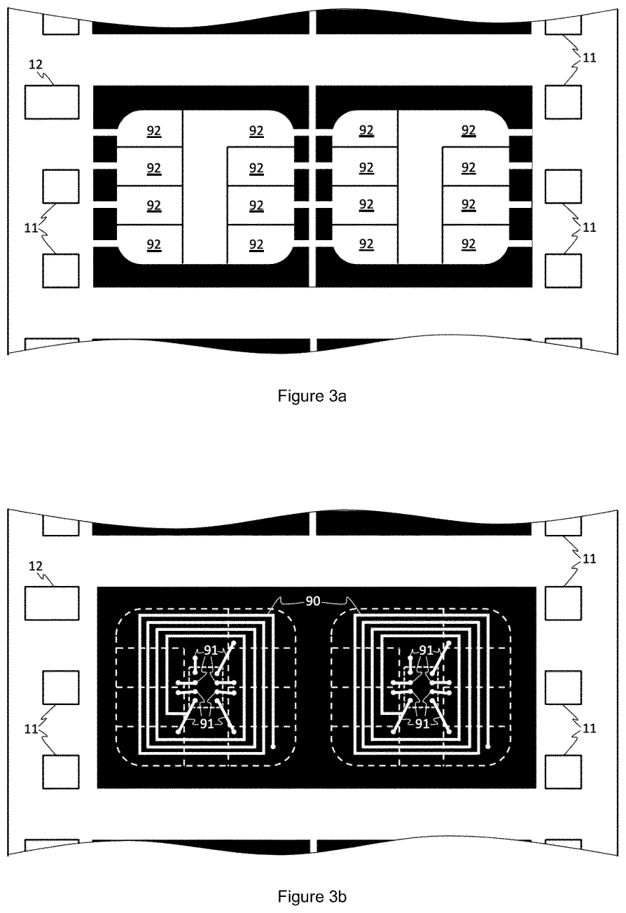

The rest of the photosensitive layers 60 are then completely removed, leaving visible on the rear face of the module, shown in FIG. 3a, an antenna 90 and the metal conductors 91 which connect the contact pads of the circuit integrated into the grid of contacts 92 of the front face of the module, shown in FIG. 3b. The modules thus produced have a thickness that is for example 270 μm, which is much less than the thickness of the modules of the prior art. A person skilled in the art can use greater thicknesses of metal and dielectric material if it is desired to have a more rigid module, while still being able to obtain a module thickness lower than a module of the prior art. Furthermore, since the module is flat, the machining of the smartcard is simplified.

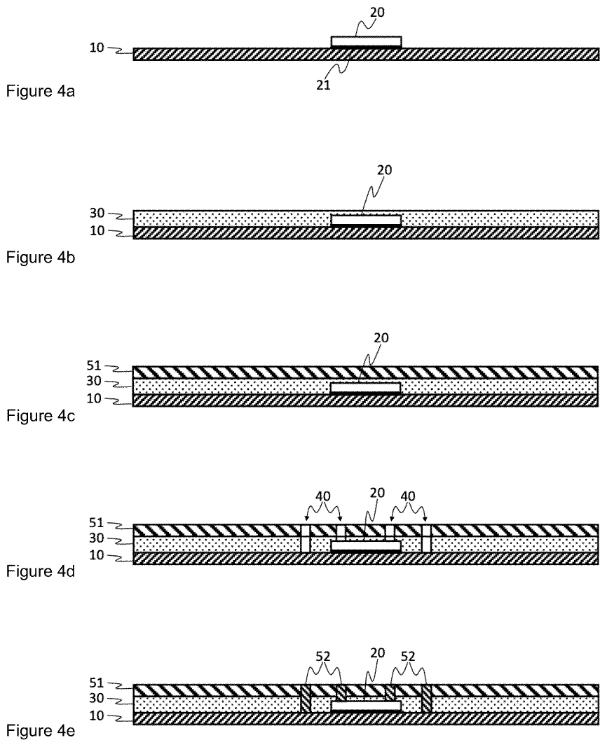

FIGS. 4a to 4e illustrate a second embodiment of the method according to the invention. FIG. 4a shows the deposition and bonding of an integrated circuit 20 on the metal strip 10, identically to what is carried out in FIG. 2a. Then a layer of a dielectric material 30 is deposited in the liquid phase to cover the metal strip 10 and the integrated circuit 20, as shown in FIG. 4b. In this second example, the dielectric material is a thermosetting material whose viscosity is sufficiently large to avoid creep under the effect of its own weight. In FIG. 4c, a second metal strip 51 is deposited on the layer of dielectric material 30 before a hot-rolling step. The second metal strip 51 is for example a 35 mm thick copper strip which makes it possible to avoid a release film. Thus, hot-rolling is carried out using a press with a controlled pressing height to roll the two metal strips 10 and 51 enclosing the layer of dielectric material 30 and to heat the assembly until the dielectric layer is cured.

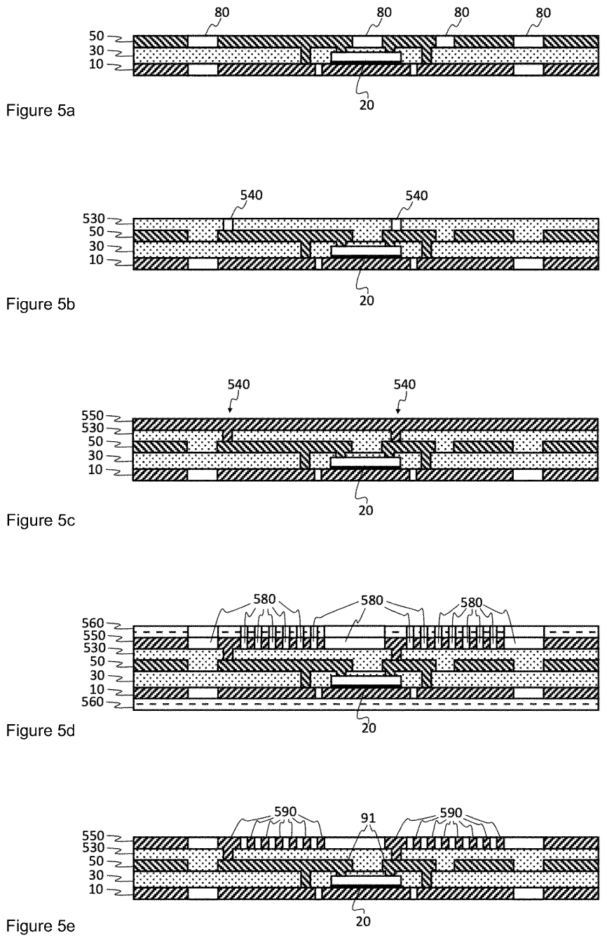

A step of producing openings is carried out, as shown in FIG. 5d. Openings 40 are produced for example using a YAG laser which will vaporize the metal of the second metallic strip 51 and the dielectric material at locations corresponding to contact locations. The contact locations are positioned relative to the marker so that the openings correspond to contact pads of the integrated circuit 20 and to locations where it is desired to make contact with the metal strip 10.

Then, a conducting layer 52 is deposited as shown in FIG. 5e. The conducting layer 52 is deposited to fill the openings 40. As an example, the conducting layer 52 is deposited locally by metal sputtering or by any other metallization method making it possible to control the location of the metal deposition.

To finish the printed circuit, a step of etching the metal strips 10 and 51 is then carried out according to a known technique. As a preferred example, the etching step is carried out by photolithography and acid attack as shown in FIGS. 2e to 2h.

A person skilled in the art will understand that the second embodiment has fewer manufacturing steps although the production of the metallization of the openings is more complex. In addition, this second example makes it possible to obtain a better surface condition for the conductors located on the rear part of the module.

The smartcard module produced according to one of the two embodiments comprises a near-field antenna 90 whose size is limited to the center by the metal conductors 91. Furthermore, to be able to close the antenna 90, the latter is connected to the contacts C4 and C8 of the contact grid, which is only possible for the modules having eight contacts. The advantage of obtaining so thin a module also makes it possible to add a third conducting layer while having a thickness less than the thickness of a module of the prior art. The use of a third conducting layer makes it possible to produce an antenna on the third layer without the latter being limited by the metal conductors or only requiring connection to contact pads.

FIGS. 5a to 5f illustrate an embodiment of a method making it possible to add a third conducting layer to a module according to the invention. In FIG. 5a, an etched module obtained from one of the preceding examples is provided in a strip. Such a module for example has a thickness of 270 μm.

A layer of dielectric material 530 is deposited on the metallic layer 50 in liquid phase over a thickness of the order of 60 μm. The dielectric layer is then hot rolled to be hardened in the same way as described in the first embodiment in relation to FIG. 2b. However, the hot-rolling height is set to reduce the layer to 50 μm of thickness so that the layer of dielectric material does indeed fill the openings 80 of the metallic layer 50. After hardening, openings 540 are then made in the dielectric layer 530. The creation of the openings 540 is carried out for example using a YAG laser which will vaporize the dielectric material at locations corresponding to contact locations. The contact locations are positioned relative to the marker so that the openings correspond to conductive areas of the metallic layer 50 for which an electrical contact is desired with the third metallic layer.

Then a deposition of a conducting layer 550 is carried out as shown in FIG. 5c. The conducting layer 550 is deposited to cover the entire dielectric layer 530 and to fill the openings 540. As a preferred example, the conducting layer 550 is deposited in two stages. Firstly, a conductive priming material is deposited over the entire surface and then an electro-deposition of a metal, for example copper, is then carried out on the carbon layer to improve the conductivity of the conducting layer 550. Electrodeposition is carried out until a copper layer about 35 μm thick is obtained. The conducting layer 550 thus produced is connected to conductive areas of the metallic layer 50 which allow an interconnection to the metal strip 10 and/or the contact areas of the chip 20.

The conducting layer 550 is then etched, as shown in FIG. 5d. The step of etching the conducting layer 550 is carried out according to a known technique. As a preferred example, the etching step is carried out by photolithography and acid attack. Layers 560 of photosensitive material are deposited on the metallic layer 550 and on the lower surface of the metal strip 10. However, only the photosensitive layer 560 deposited on the metallic layer 550 is exposed to UV using a mask, the photosensitive layer 560 deposited on the metal strip serving only to protect the metal strip 10 during the acid bath. As the strip passes through the acid bath, openings 580 are made in the conducting layer 550.

The photosensitive layers 560 are then completely removed using a solvent, as shown in FIG. 5e. Thus, the rear face of the module may comprise an antenna 590 connected to metal conductors 91 located on the metallic layer 50. The module thus produced, although it has three metallic layers, has a thickness of 345 μm, which is much less than a module of the prior art.

The method of the invention is not limited to the manufacture of a smartcard module comprising a single chip. One or more active or passive components may also be placed in the dielectric layer, it would be advisable to adapt the thickness of the dielectric layer to the height of the thickest component.

1. A method for manufacturing a smartcard module wherein it comprises the steps of:
providing a first metal foil comprising at least one marker,
depositing and bonding at least one electronic component on an upper face of said metal foil at a location positioned relative to the at least one marker,
depositing a first layer of dielectric material; on the upper face of the metal foil and on the electronic component,
making openings in the first layer of hardened dielectric material,
depositing a first conducting layer covering the entire surface of the first layer of dielectric material,
depositing a second conducting layer filling the openings,
etching the first metal foil and the first conducting layer in order to create patterns of conductors, the etching of the first metal foil forming a smartcard contact grid.

2. The method for manufacturing a smartcard module according to claim 1, wherein the steps of depositing the first and second conducting layers are carried out simultaneously and comprise a step of depositing a conductive priming material on the first layer of dielectric material and in the openings, followed by a step of electrodeposition of copper.

3. The method for manufacturing a smartcard module according to claim 1, wherein the step of depositing the first conducting layer is done by depositing a second metal foil prior to the hot rolling step and the step of producing openings simultaneously produces openings in the first layer of dielectric material and in the second metal foil.

4. The method for manufacturing a smartcard module according to claim 1, wherein the step of making openings is carried out by laser.

5. The method for manufacturing a smartcard module according to claim 1, wherein the dielectric material is chosen from one of the following materials: polyester, epoxy resin, polyimide.

6. The method for manufacturing a smartcard module according to claim 1, wherein the first layer of dielectric material is a thermosetting material deposited in liquid or pasty phase and wherein the method comprises a step of hot rolling in order to flatten and harden the first layer of dielectric material.

7. The method for manufacturing a smartcard module according to claim 6, wherein the hot rolling step is carried out using a press having a control of the pressing height.

8. The method for manufacturing a smartcard module according to claim 1, wherein the electronic component is an integrated circuit.

9. The method for manufacturing a smartcard module according to claim 1, wherein the step of etching the first metal foil and the first conducting layer comprises the steps of:
depositing photosensitive layers on the first conducting layer and on the bottom surface of the first metal foil,
insulating the photosensitive layers with a negative mask of the patterns defining the parts to be insulated,
removing the insulated part; of the photosensitive layers,
acid-etching the first conducting layer; and the bottom surface of the first metal foil on the areas where the insulated photosensitive layers have been removed.

10. The method for manufacturing a smartcard module according to claim 1, wherein, at the end of the step of etching the first conducting layer, said method comprises the following steps:
depositing a second layer of dielectric material on the first etched conducting layer,
hot-rolling in order to flatten and harden the second layer of dielectric material,
making openings; in the second layer of hardened dielectric material,
depositing a third conducting layer; covering the entire surface of the second layer of dielectric material,
depositing a fourth conducting layer filling the openings,
etching the third conducting layer in order to produce patterns of conductors.

11. The method for manufacturing a smartcard module according to claim 10, wherein the step of etching the third conducting layer comprises the steps of:
depositing a photosensitive layer on the third conducting layer,
insulating the photosensitive layer with a mask defining the parts to be insulated,
removing the insulated part of the photosensitive layer,
acid-etching the third conducting layer on the areas where the insulated photosensitive layer has been removed.

12. A smartcard module comprising a first metallic layer and a second metallic layer enclosing a layer of dielectric material, the first metallic layer defining a grid of contacts; intended to be flush with the surface of a smartcard, the second metallic layer being etched with patterns defining metal conductors to connect contact pads of a circuit integrated into the grid of contacts through openings made in the layer of dielectric material wherein the integrated circuit is placed between the first and second; metallic layers inside the layer of dielectric material.

13. The smartcard module according to claim 12, which comprises a third metallic layer separated from the second metallic layer by a second dielectric layer, the second metallic layer being between the first and third metallic layers.
